(19) United States
(12) Patent Application Publication
(10) Pub. No.: US 2018/0269016 A1
(43) Pub. Date: Sep. 20, 2018

(54) VEHICLE SWITCH

(71) Applicant: KELSEY-HAYES COMPANY, Livonia, MI (US)

(72) Inventors: SUDHAKAR GUDIMALLA, Farmington Hills, MI (US); madan Mohan Padarthi, Canton, MI (US); Vivek V. Mohile, West Bloomfield Township, CT (US); Jeffrey Wiersing, Walled Lake, MI (US); Roberto Tomassi, Livonia, MI (US)

(21) Appl. No.: 15/921,036

(22) Filed: Mar. 14, 2018

Related U.S. Application Data
(60) Provisional application No. 62/471,120, filed on Mar. 14, 2017.

(51) Int. Cl. H01H 36/00; B60K 35/00; G01D 5/14

(52) U.S. Cl. CPC H01H 36/00; B60K 35/00; H01H 2231/026; H01H 2221/044; G01D 5/145

(57) ABSTRACT

A vehicle switch including a housing and an actuator movably supported in the housing. A magnet is connected to the actuator. A sensor senses the position of the magnet and sends a signal indicating the position of the magnet to control a vehicle function.

### RELATED APPLICATIONS

This application claims the benefit of U.S. Appln. Ser. No. 62/471,120, filed Mar. 14, 2017, the entirety of which is incorporated herein by reference.

### FIELD OF THE INVENTION

The present invention is directed to a vehicle switch and, more specifically, to a contactless vehicle switch.

### BACKGROUND

A known vehicle switch typically has electrical contacts that engage each other.

### SUMMARY OF THE INVENTION

The present invention is directed to a vehicle switch including a housing and an actuator movably supported in the housing. A magnet is connected to the actuator. A sensor senses the position of the magnet and sends a signal indicating the position of the magnet to control a vehicle function.

### BRIEF DESCRIPTION OF THE DRAWINGS

The foregoing and other features and advantages of the present invention will become apparent to one skilled in the art upon consideration of the following description of the invention and the accompanying drawings, in which:

FIG. 1 is an exploded view of a first embodiment of a vehicle switch constructed in accordance with the present invention;

FIG. 2 is a cross-sectional view of the vehicle switch of FIG. 1;

FIG. 3 is an exploded view of a second embodiment of a vehicle switch constructed in accordance with the present invention;

FIG. 4 is a cross-sectional view of the vehicle switch of FIG. 3;

FIG. 5 is an exploded view of a third embodiment of a vehicle switch constructed in accordance with the present invention;

FIG. 6 is a cross-sectional view of the vehicle switch of FIG. 5.

FIG. 7 is an exploded view of a fourth embodiment of a vehicle switch constructed in accordance with the present invention;

FIG. 8 is a cross-sectional view of the vehicle switch of FIG. 7; and

FIG. 9 is an enlarged view of a portion of the vehicle switch of FIG. 8.

### DETAILED DESCRIPTION

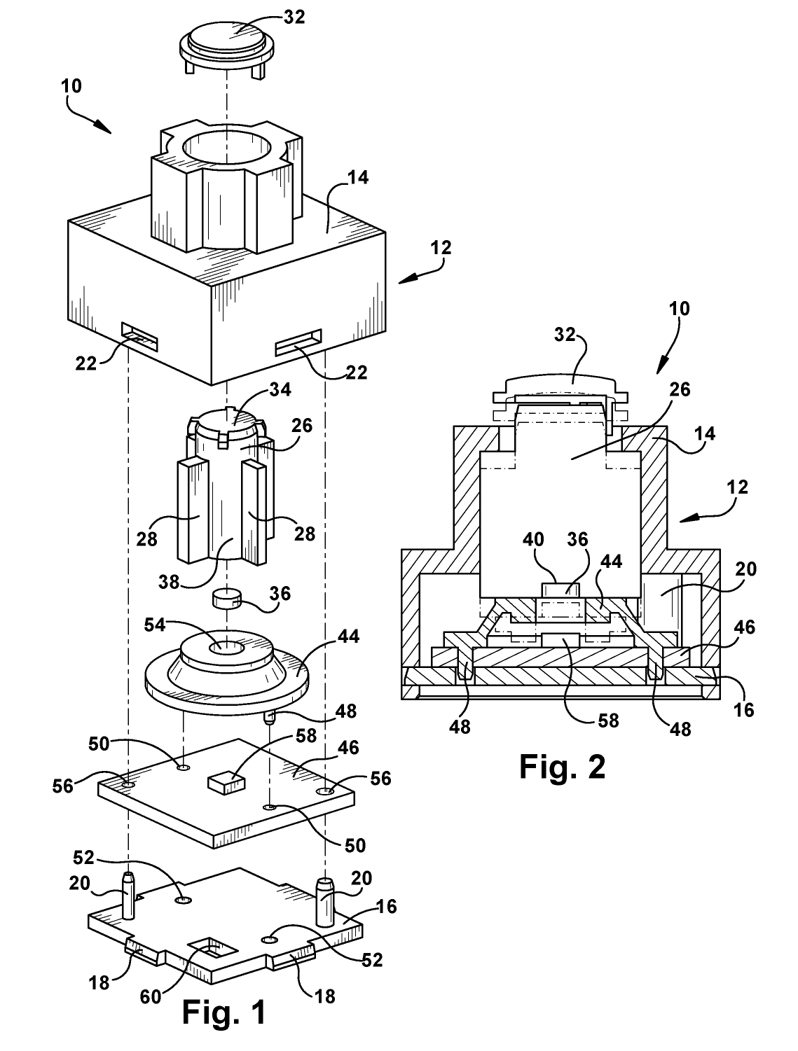

A vehicle switch 10, constructed in accordance with the present invention, is illustrated in FIGS. 1-2. The switch 10 includes a housing 12 that has a body portion 14 and a cover 16. The cover 16 may include tabs 18 and pins 20. The tabs 18 may extend into openings 22 in the body portion 14 to connect the cover 16 to the body portion. The pins 20 may extend into openings in the body portion 14 to help secure the cover 16 to the body portion.

An actuator 26 is supported in the housing 12 for axial movement relative to the housing. The actuator 26 has radially extending guide members 28 that engage an inner surface of the body portion 14 of the housing 12. The guide members 28 guide axial movement of the actuator relative to the housing 12.

A button 32 is connected with a first or upper axial end portion 34 of the actuator 26. The button 32 moves with the actuator 26 relative to the housing 12. A magnet 36 is connected with a second or lower axial end portion 38 of the actuator 26. The magnet 36 may be located in a recess 40 in the lower axial end portion 38 of the actuator 26 and connected to the actuator in any desired manner. The magnet 36 moves with the actuator 26 and the button 32 relative to the housing 12. The button 32 is pressed by an operator to axially move the button, the actuator 26 and the magnet 36 relative to the housing 12.

The second axial end portion 38 of the actuator 26 engages a biasing member, such as an elastomer pad 44. The elastomer pad 44 is connected to a printed circuit board (PCB) 46. The elastomer pad 44 may have a plurality of projections 48 that extend through openings 50 in the printed circuit board 46 and into openings 52 in the cover 20 to connect the elastomer pad to the PCB and the cover. The elastomer pad 44 urges the actuator 26 away from the PCB 46. The elastomer pad 44 may include a central opening 54 adjacent the magnet 36.

The PCB 46 is supported by the cover 16. The pins 20 on the cover 16 extend through openings 56 in the PCB 46 to help secure the PCB to the housing 12. A sensor 58, such as a Hall effect sensor, is mounted on the PCB 46 at a central location and axially below the magnet 36 and the opening 54 in the elastomer pad 44. The sensor 58 is spaced from the magnet 36 by the elastomer pad 44. The Hall effect sensor 58 may be a Hall effect micro chip. The cover 16 has at least one opening 60 through which electrical leads extending from the Hall sensor 58 and PCB 46 may extend.

Upon pressing of the button 32 by an operator, the actuator 26 and the magnet 36 move axially relative to the housing 12 toward the sensor 58. The sensor 58 senses the axial movement of the magnet 36 relative to the housing 12 and the PCB 56 and sends a signal to a controller indicating movement of the magnet. Upon release of the button 32, the elastomer pad 44 moves the magnet 44 and actuator 26 axially relative to the housing 12 away from the sensor 58. The switch 10 may be an on/off switch. The switch 10 may turn on a vehicle function upon pressing the button 32 if the function is turned off. The switch 10 may turn off the vehicle function upon pressing the button 32 if the vehicle function is turned on. The switch 10 may be used to turn any desired vehicle function on and off, such as a heater for a steering wheel or vehicle seat.

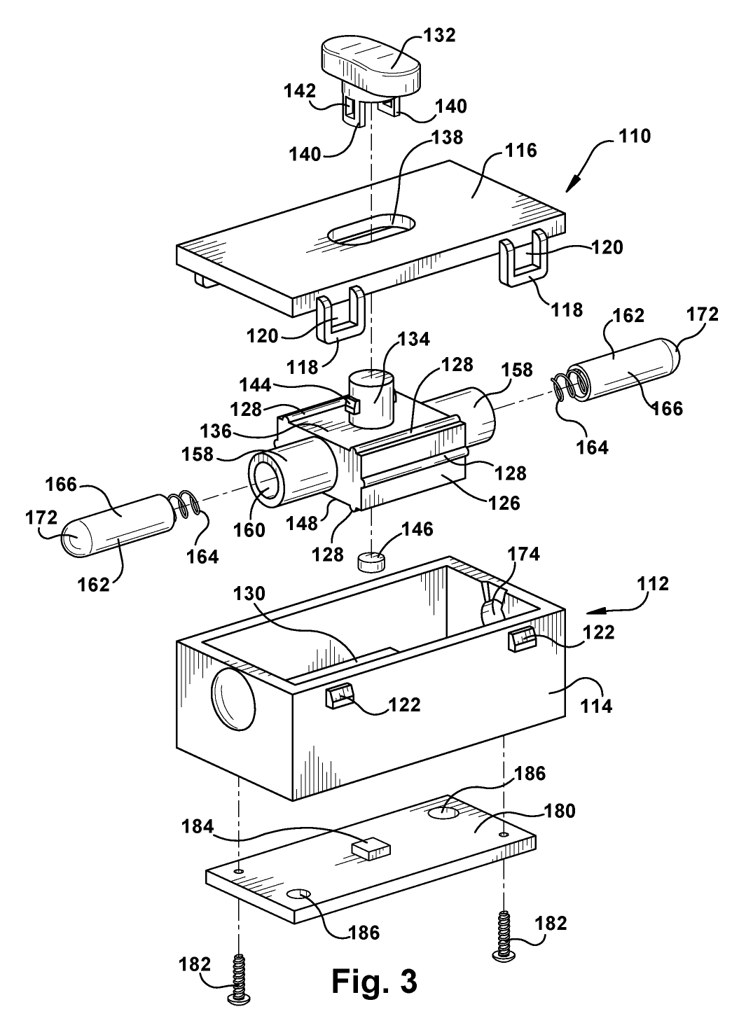

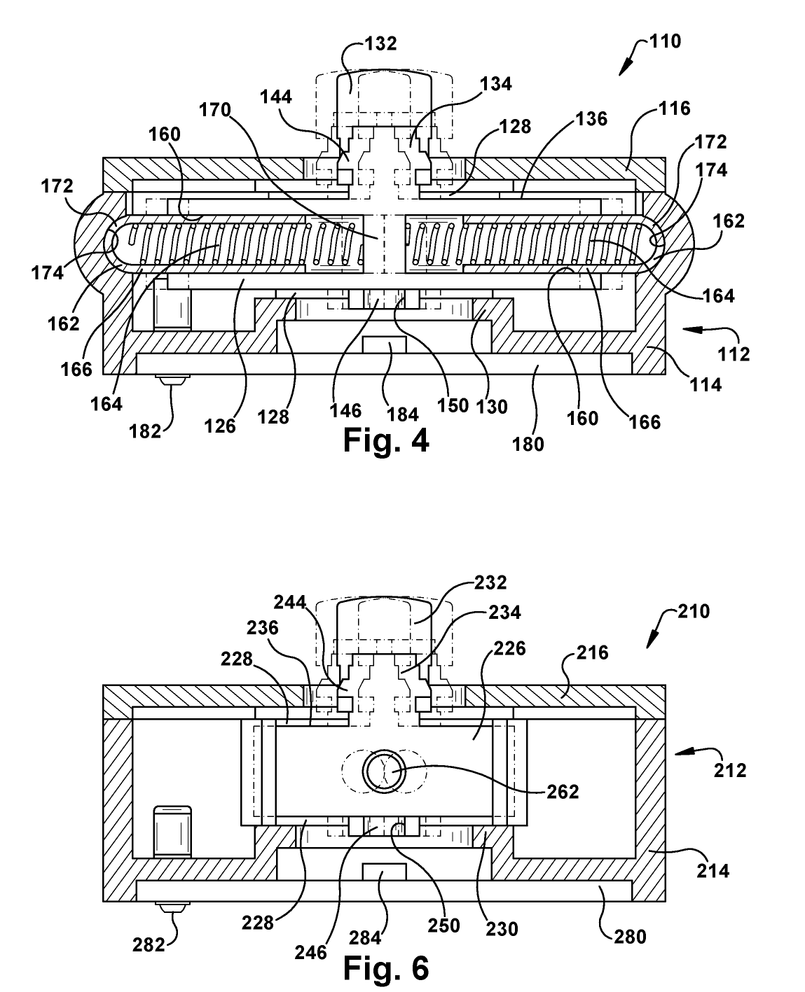

A second embodiment of a vehicle switch 110 constructed in accordance with the present invention is illustrated in FIGS. 3-4. The switch 110 includes a housing 112 that has a body portion 114 and a cover 116. The cover 116 may include tabs 118 with openings 120. The body portion 114 may have tabs 122 that extend into the openings 120 to connect the cover 116 to the body portion.

An actuator 126 is supported in the housing 112 for sliding movement relative to the housing. The actuator 126 has guide members 128 extending from sides of the actuator. The guide members 128 engage ledges 130 inside the body portion 114 of the housing 112. The ledges 130 support the actuator for sliding movement of the actuator 126 relative to the housing 112. The guide members 128 also engage the cover 116 and inner side surfaces of the body portion 114 to guide movement of the actuator 126 relative to the housing 112.

A button 132 is connected with a connecting portion 134 of the actuator 126. The button 132 moves with the actuator 126 relative to the housing 112. The connecting portion 134 extends from a first or upper surface 136 of the actuator 126 through an opening 138 in the cover 116. The button 132 may include tabs 140 with openings 142. The connecting portion 134 may have tabs 144 that extend into the openings 142 to connect the button 132 to the actuator 126.

A magnet 146 is connected with a second or lower surface 148 of the actuator 126. The magnet 146 may be located in a recess 150 in the lower surface 148 of the actuator 126 and connected to the actuator in any desired manner. The magnet 146 moves with the actuator 126 and the button 132 relative to the housing 112. The button 132 is moved by an operator to slide the button, the actuator 126 and the magnet 146 relative to the housing 112.

The actuator 126 includes cylindrical portions 158 extending in opposite directions from the actuator and generally parallel to the guide members 128. Each of the cylindrical portions 158 has an opening 160. First and second biasing members or spring plungers 162 extend into the openings 160. Each of the spring plungers 162 includes a spring 164 and a plunger 166. The springs 164 extend into the actuator 126 and engage an inner wall 170 of the actuator. The springs 164 extend into the plungers 166 and engage end portions of the plungers 166 to urge the plungers outwardly away from each other. The spring plungers 162 urge the actuator into a centered initial position relative to the housing 112. Axial end portions 172 of the plungers 166 extend into recesses 174 in the body portion 114 of the housing 112. The axial end portions 172 of the plungers 166 may have semi-spherical shapes that match semi-spherical shapes of the recesses 174. The semi-spherical shapes of the axial end portions 172 of the plungers 166 and the recesses 174 help to align the actuator 126 in the housing 112.

A printed circuit board (PCB) 180 is connected to the body portion 114 of the housing 112 so that the actuator 126 is located between the PCB and the cover 116. The PCB 180 may be connected to the body portion 114 by fasteners 182. A sensor 184, such as a Hall effect sensor, is mounted on the PCB 180 at a central location and below the magnet 146. The Hall effect sensor 184 may be a Hall effect micro chip. The sensor 184 is spaced from the magnet 146 by the ledge 130. The PCB 180 has at least one opening 186 through which electrical leads extending from the Hall sensor 184 and PCB 180 may extend.

Upon sliding the button 132 from the initial position toward one of the spring plungers 162 relative to the housing 112 by an operator, the actuator 126 and the magnet 146 move parallel to the PCB 180 and the cover 116 relative to the housing 112 and the sensor 184. The sensor 184 senses the movement of the magnet 146 relative to the housing 112 and the PCB 180 and sends a signal to a controller indicating movement of the magnet. Upon release of the button 132, the spring plungers 162 move the magnet 146 and actuator 126 relative to the housing 112 into the initial or central position. The switch 110 may be an on/off switch. The switch 110 may turn on a vehicle function upon moving or sliding the button 132 in a first direction, such as to the right in FIG. 4. The switch 110 may turn off the vehicle function upon moving or sliding the button 132 in a second opposite direction, such as to the left in FIG. 4. The switch 110 may be used to turn any desired vehicle function on and off, such as a heater for a steering wheel or vehicle seat.

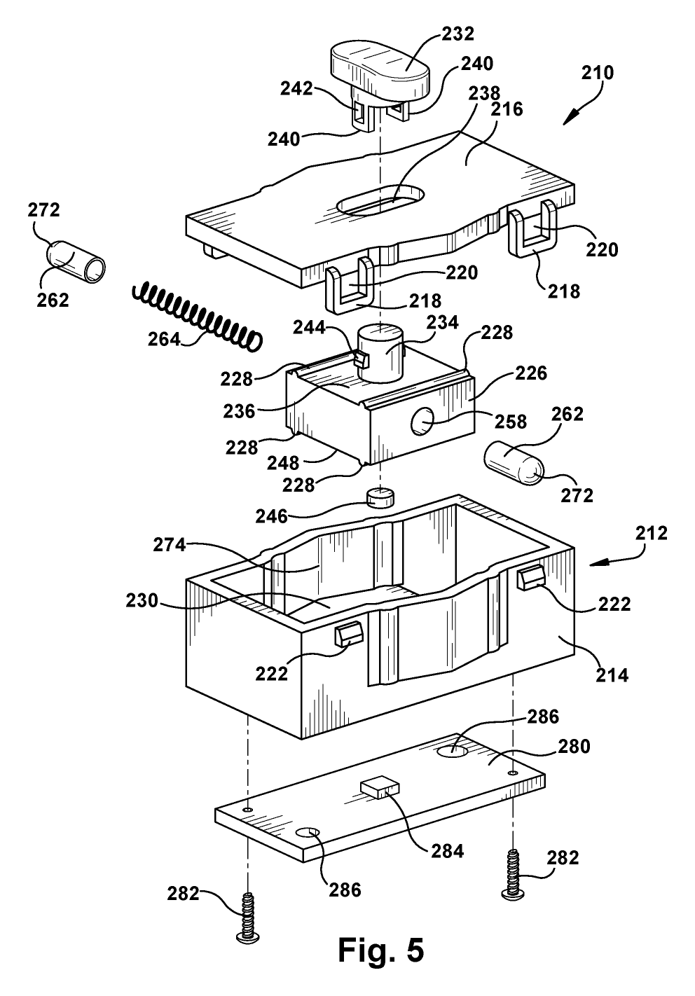

Another embodiment of a vehicle switch 210 constructed in accordance with the present invention is illustrated in FIGS. 5-6. The switch 210 includes a housing 212 that has a body portion 214 and a cover 216. The cover 216 may include tabs 218 with openings 220. The body portion 214 may have tabs 222 that extend into the openings 220 to connect the cover 216 to the body portion.

An actuator 226 is supported in the housing 212 for sliding movement relative to the housing. The actuator 226 has guide members 228 extending from the actuator. The guide members 228 engage ledges 230 inside the body portion 214 of the housing 212. The ledges 230 support the actuator 226 for sliding movement relative to the housing 212. The guide members 228 also engage the cover 216 to guide movement of the actuator 226 relative to the housing 212.

A button 232 is connected with a connecting portion 234 of the actuator 226. The button 232 moves with the actuator 226 relative to the housing 212. The connecting portion 234 extends from a first or upper surface 236 of the actuator 226 through an opening 238 in the cover 216. The button 232 may include tabs 240 with openings 242. The connecting portion 234 may have tabs 244 that extend into the openings 242 to connect the button 232 to the actuator 226.

A magnet 246 is connected with a second or lower surface 248 of the actuator 226. The magnet 246 may be located in a recess 250 in the lower surface 248 of the actuator 226 and connected to the actuator in any desired manner. The magnet 246 moves with the actuator 226 and the button 232 relative to the housing 212. The button 232 is moved by an operator to slide the button, the actuator 226 and the magnet 246 relative to the housing 212.

The actuator 226 includes a cylindrical opening 258 extending through the actuator and generally perpendicular to the guide members 228. First and second biasing members or spring plungers 262 extend into the opening 258. A spring 264 extends through the actuator 226 and into the plungers 262. The spring 264 engages end portions of the plungers 262 to urge the plungers outwardly away from each other. The spring plungers 262 urge the actuator 226 into a centered initial position relative to the housing 212.

Axial end portions 272 of the plungers 262 extend into recesses 274 in the body portion 214 of the housing 212. The axial end portions 272 of the plungers 262 may have semi-spherical shapes. The semi-spherical shapes of the axial end portions 272 of the plungers 262 and the recesses 274 help to align the actuator 226 in the housing 212.

A printed circuit board (PCB) 280 is connected to the body portion 214 of the housing 212 so that the actuator is located between the PCB and the cover 216. The PCB 280 may be connected to the body portion 214 by fasteners 282. A sensor 284, such as a Hall effect sensor, is mounted on the PCB 280 at a central location and below the magnet 246. The Hall effect sensor 284 may be a Hall effect micro chip. The sensor 284 is spaced from the magnet 246 by the ledge 230. The PCB 280 has at least one opening 286 through which electrical leads extending from the Hall sensor 284 and PCB 280 may extend.

Upon sliding the button 232 from the initial position transverse to the spring plungers 262 relative to the housing 212 by an operator, the actuator 226 and the magnet 246 move parallel to the PCB 280 and the cover 216 relative to the housing 212 and the sensor 284. The sensor 284 senses the movement of the magnet 246 relative to the housing 212 and the PCB 280 and sends a signal to a controller indicating movement of the magnet. Upon release of the button 232, the spring plungers 262 move the magnet 246 and actuator 226 relative to the housing 212 into the initial or central position. The switch 210 may be an on/off switch. The switch 210 may turn on a vehicle function upon moving or sliding the button 232 in a first direction, such as to the right in FIG. 6. The switch 210 may turn off the vehicle function upon moving or sliding the button 232 in a second opposite direction, such as to the left in FIG. 6. The switch 210 may be used to turn any desired vehicle function on and off, such as a heater for a steering wheel or vehicle seat.

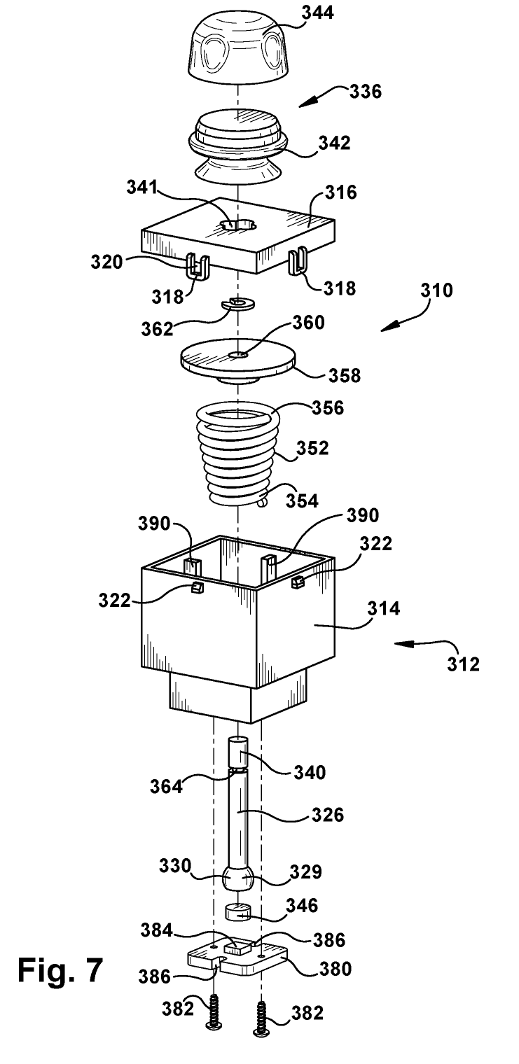

Another embodiment of a vehicle switch 310 constructed in accordance with the present invention is illustrated in FIGS. 7-9. The switch 310 includes a housing 312 that has a body portion 314 and a cover 316. The cover 316 may include tabs 318 with openings 320. The body portion 314 may have tabs 322 that extend into the openings 320 to connect the cover 316 to the body portion.

An actuator 326 is supported in the housing 312 for axial and pivotal movement relative to the housing. The actuator 326 (FIG. 9) extends through an opening 327 in a wall 328 of the housing 312. The actuator 326 has a first or lower axial end portion 329 with a spherical surface 330. The spherical surface 330 of the actuator engages a spherical recess 334 in the body portion 314 of the housing 312. The spherical recess 334 guides pivotal movement of the actuator 326 relative to the housing 312.

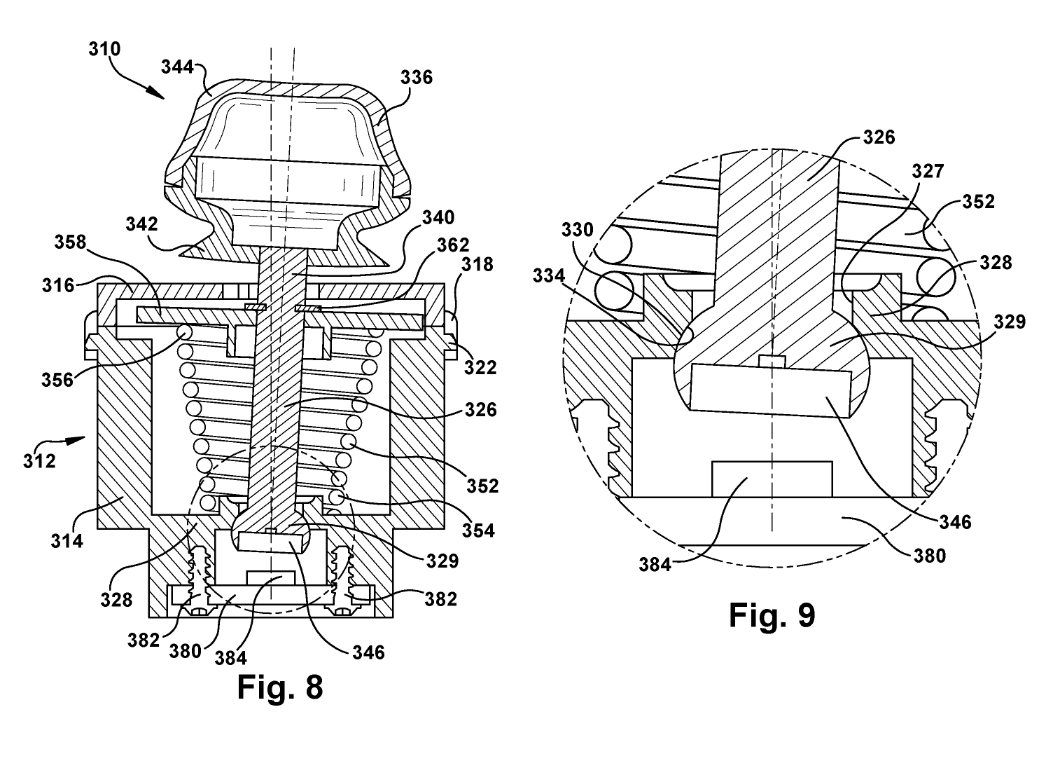

A button or knob 336 (FIGS. 7-8) is connected with a second or upper axial end portion 340 of the actuator 326. The button 336 moves with the actuator 326 relative to the housing 312. The upper axial end portion 340 of the actuator 326 extends through an opening 341 in the cover 316. The button 336 includes a knob actuator 342 connected to the upper axial end portion 340 of the actuator 326. A knob cap 344 is connected to the knob actuator 342.

A magnet 346 is connected with the first or lower axial end portion 329 of the actuator 326. The magnet 346 moves with the actuator 326 and the button 336 relative to the housing 312. The button 336 may be pressed by an operator to axially move the button, the actuator 326 and the magnet 346 relative to the housing 312. The button 336 may also be moved by an operator to pivot the button, the actuator 326 and the magnet 346 relative to the housing 312.

A biasing member 352, such as a conical spring, may urge the spherical surface 330 of the actuator 326 toward the spherical surface 334 of the housing 312. A first or lower axial end 354 of the spring 352 engages the wall 328. A second or upper axial end 356 of the spring 352 engages a disc 358. The actuator 326 extends through the spring 352 and an opening 360 in the disc 358. A lock clip 362 engages a groove 364 on the actuator 326 to retain the disc on the actuator. The spring 352 urges the disc 358 into engagement with the lock clip 362 and the spherical surface 330 of the actuator 326 toward the spherical surface 334 of the housing 312.

A printed circuit board (PCB) 380 is connected to the body portion 314 of the housing 312 so that the actuator 326 is located between the PCB and the cover 316. The PCB 380 may be connected to the body portion 314 by fasteners 382. A sensor 384, such as a Hall effect sensor, is mounted on the PCB 380 at a central location and below the magnet 346. The Hall effect sensor 384 may be a Hall effect micro chip. The sensor 384 is spaced from the magnet 346 by the spring 352. The PCB 380 has at least one opening 386 through which electrical leads extending from the Hall sensor 384 and PCB 380 may extend.

Upon pressing of the button 336 by an operator, the actuator 326, the disc 358, and the magnet 346 move axially relative to the housing 312 toward the sensor 384. The sensor 384 senses the axial movement of the magnet 346 relative to the housing 312 and the PCB 380 and sends a signal to a controller indicating movement of the magnet. The body portion 314 of the housing 312 may include stops 390. The disc 358 may engage the stops 390 to prevent the magnet 346 from engaging the sensor 384. Upon release of the button 336, the spring 352 moves the magnet 346, the disc 358 and actuator 326 axially relative to the housing 312 away from the sensor 384. The switch 310 may turn on a vehicle function upon pressing the button 336 if the function is turned off. The switch 310 may turn off the vehicle function upon pressing the button 336 if the vehicle function is turned on. The switch 310 may be used to turn any desired vehicle function on and off, such as a tilt/telescope function.

The switch 310 may also be used to control the vehicle function when the function is turned on. Upon pivoting the button 336 by an operator, the actuator 326 and the magnet 346 move relative to the housing 312 and the sensor 384. The sensor 384 senses the pivotal movement of the magnet 346 relative to the housing 312 and the PCB 380 and sends a signal to a controller indicating movement of the magnet. Upon release of the button 336, the spring 352 moves the magnet 346 and actuator 326 relative to the housing 312 to an initial position. The switch 310 may be used to control any desired vehicle function, such as controlling the position of a vehicle steering column.

From the above description of the invention, those skilled in the art will perceive improvements, changes and modifications. For example, it is contemplated that the switches may control any desired functions of the vehicle. Such improvements, changes and modifications within the skill of the art are intended to be covered by the appended claims.

Having described the invention, the following is claimed:

1. A vehicle switch comprising:
a housing;
an actuator movably supported in the housing;
a magnet connected to the actuator;
a sensor for sensing the position of the magnet and sending a signal indicating the position of the magnet to control a vehicle function.

2. A vehicle switch as set forth in claim 1 wherein the sensor is a Hall effect sensor.

3. A vehicle switch as set forth in claim 2 wherein the Hall effect sensor is a Hall effect micro chip.

4. A vehicle switch as set forth in claim 1 wherein the actuator and magnet move toward and away from the sensor.

5. A vehicle switch as set forth in claim 4 wherein a biasing member urges the actuator and magnet away from the sensor.

6. A vehicle switch as set forth in claim 5 wherein the biasing member is an elastomer pad engaging the actuator.

7. A vehicle switch as set forth in claim 5 wherein the biasing member is a spring through which the actuator extends.

8. A vehicle switch as set forth in claim 7 wherein the actuator and magnet are pivotable relative to housing, the spring urging the actuator to an initial pivot position relative to the housing.

9. A vehicle switch as set forth in claim 8 wherein the housing includes a spherical surface engageable with a spherical surface on the actuator to support the actuator for pivotable movement relative to the housing.

10. A vehicle switch as set forth in claim 1 where in the actuator and magnet slide relative to the housing and the sensor.

11. A vehicle switch as set forth in claim 10 wherein at least one biasing member urges the actuator and magnet to a central position.

12. A vehicle switch as set forth in claim 11 wherein the at least one biasing member includes at least one spring plunger having a spring extending into a plunger engaging the housing, the spring and the plunger extending into an opening in the actuator.

13. A vehicle switch as set forth in claim 12 wherein the spring extends through an opening in the actuator and engages plungers on opposite sides of the actuator.

14. A vehicle switch as set forth in claim 12 wherein the actuator and magnet slide toward the plunger.

15. A vehicle switch as set forth in claim 12 wherein the actuator and magnet slide transverse to the plunger.

16. A vehicle switch as set forth in claim 10 wherein the actuator includes at least one guide member slidably engaging the housing to guide sliding movement of the actuator and magnet relative to the housing and the sensor.

17. A vehicle switch as set forth in claim 1 further including a printed circuit board (PCB) connected to the housing, the sensor being connected to the PCB and spaced from the magnet.

18. A vehicle switch as set forth in claim 1 wherein the switch turns on and off a heater for a steering wheel or vehicle seat.

19. A vehicle switch as set forth in claim 1 wherein the switch controls the position of a vehicle steering column.
